(19) United States
(12) Patent Application Publication
(10) Pub. No.: US 2026/0311426 A1
(43) Pub. Date: Oct. 8, 2026

(54) Methods and Arrangements for Forming a Three-Dimensional, Kinematic Model of a System for Forming a Digital Twin of the System

(71) Applicant: SIEMENS AKTIENGESELLSCHAFT, Münvhen (DE)

(72) Inventor: Thomas Baudisch, Garching (DE)

(73) Assignee: SIEMENS AKTIENGESELLSCHAFT, Münvhen (DE)

(21) Appl. No.: 19/479,486

(22) PCT Filed: Mar. 28, 2024
(86) PCT No.: PCT/EP2024/058652

§ 371 Date: Oct. 28, 2025

(30) Foreign Application Priority Data
Apr. 28, 2023 (EP) 23170741.3

(51) Int. Cl. G06T 17/00; G06T 7/246; G06V 10/62; G06V 10/75; G06V 20/64

(52) U.S. Cl. CPC G06T 17/00; G06T 7/248; G06V 10/62; G06V 10/751; G06V 20/64; G06T 2207/10016; G06T 2207/10028; G06T 2207/30108

(57) ABSTRACT

Various embodiments include methods for forming a digital twin of the system. An example includes: creating and storing a first 3D scan of the system at a first point in time; creating and storing a second scan at a subsequent point on the basis of the capture result; capturing mobility properties of the system; analyzing the first or second scans of the system with respect to geometries formed for each scan; analyzing the scans of the system on the basis of a recording time in order to ascertain movable and immovable geometries of the respective scan of the system; ascertaining a property of the movement for each movable 3D geometry; determining a type of each connection element between movable and immovable geometries; generating the three-dimensional model using the captured geometries and the determined elements; and supplying the model as the basis for forming the digital twin.

### CROSS-REFERENCE TO RELATED APPLICATIONS

This application is a U.S. National Stage Application of International Application No. PCT/EP2024/058652 filed Mar. 28, 2024, which designates the United States of America, and claims priority to EP Application No. 23170742.3 filed Apr. 28, 2023, the contents of which are hereby incorporated by reference in their entirety.

### TECHNICAL FIELD

The presented disclosure relates to system modeling. Various embodiments of the teachings herein include methods and/or systems for forming a three-dimensional, kinematic model of a system, in particular in the industrial environment, for forming a digital twin of the system.

### BACKGROUND

It is known practice to operate a digital twin in parallel with real objects of the physical world, for example a system, in particular in the industrial environment. As a result, use in the form of a so-called “industrial metaverse” becomes possible in the industrial environment. Such use allows virtual and augmented realities to also be included in industrial production and maintenance, thus making it possible, for example, to optimize processes or to increase the production efficiency and to support remote work and training.

In the context of the industrial metaverse, this digital twin is a realistic 3D model of the real system. 3D models can be created either by manually inputting data and/or by 3D scanning a physical object. In order to manually input data, use is usually made of tools of a computer-assisted design method, such as the so-called “computer aided design”, CAD, or similar software that sets up the digital model of the object with three dimensions in order to subsequently display it on a computer screen.

This creation of 3D models often requires thorough knowledge of geometry and materials sciences in order to create a realistic, functional model. The creation of the 3D model may signify an enormous outlay, in particular if the creation is carried out manually, in particular in connection with existing systems, for which there are no 3D CAD data or other models which can be used during creation.

### SUMMARY

The teachings of the present disclosure include systems and methods for forming a three-dimensional, kinematic model of a system, in particular in the industrial environment, for forming a digital twin of the system. Some examples include a computer-assisted method for forming a three-dimensional, kinematic model of a system, in particular in the industrial environment, for forming a digital twin of the system, characterized in that the following are carried out: a) a first 3D scan of the system is created and stored at a first point in time by a first module, b) at least one second 3D scan of the system is created and stored at at least one subsequent, second point in time by a second module on the basis of the capture result, c) mobility properties of the system are captured by a third module, d) the first 3D scan and/or the second 3D scans of the system is/are analyzed by a fourth module with respect to 3D geometries formed, in particular according to CAD methods, for each 3D scan, e) the 3D scans of the system are analyzed by the fifth module on the basis of at least the recording time in order to ascertain movable and immovable 3D geometries of the respective scan of the system, f) at least one property of the movement is ascertained for each movable 3D geometry by a sixth module, g) the type of connection elements, for example joint type, between movable and immovable 3D geometries is determined by a seventh module, and h) the three-dimensional model is generated on the basis of the captured 3D geometries and the determined elements and is supplied to an eighth module as the basis for forming a digital twin.

In some embodiments, depending on whether the mobility property is such that the system has at least one movable element, second 3D scans are captured and stored at so many second points in time that a 3D scan is captured and stored for each movable element substantially at all positions that can be assumed.

In some embodiments, the second points in time are continued in such a manner that a continuous sequence of 3D scans, in particular representing a flowing movement during visualization for an observer, is captured and stored.

In some embodiments, the second points in time are continued in such a manner that a sequence of 3D scans representing discrete locations, in particular at least end positions and/or turning points of a moving part of the system, in particular during visualization for an observer, is captured and stored.

In some embodiments, data describing a point cloud resulting in each case from the respective 3D scan are created and stored by an eighth module from at least a portion, in particular starting points, end points and/or turning points, of the stored 3D scans.

In some embodiments, on the basis of the data describing point clouds, a tenth module a) compares 3D geometries determined by means of defined point cloud information, and stored in particular in a database, a cloud memory or the like, with points in the respective resulting point cloud, and b) if a stored geometry matches, converts the matching part of the point cloud into the 3D geometry.

In some embodiments, a digital image sequence is generated for each moving stored geometry element in such a manner that, for each 3D scan, a) a digital image is created on the basis of the 3D geometries, b) wherein a fixed stored 3D geometry associated with the respective moving 3D geometry is created as a first representation within the digital image, and the moving 3D geometry is created as a second representation within the digital image, c) and wherein the image sequence is created in such a manner that the second representation is placed in the respective point cloud resulting from the 3D scan in such a manner that the moving 3D geometry is gradually tracked within the boundary given by the resulting point cloud for each point cloud resulting from the 3D scan, and d) the resulting image sequence is supplied to an image processing algorithm performed by an eleventh module in such a manner that the image processing algorithm carries out a pattern recognition using the image sequence in such a manner that a comparison with the movement patterns of known movable connection elements, in particular joints, is carried out and, if there is a match, the type of connection element is output as recognized and as an output signal in such a manner that a 3D geometry representing the connection element is defined.

In some embodiments, parameters of the connection element, in particular physical variables defining a movement profile, for example speed and/or acceleration, and/or geographical variables, such as end positions of the movement, are derived on the basis of the 3D scans.

In some embodiments, the digital twin can be operated in a parameterized manner using the 3D model in such a manner that its state, on account of at least one parameter input, experiences a change which is output so as to be usable as the basis for an adjustment during operation and/or when setting up the system.

As another example, some embodiments include an arrangement for forming a three-dimensional model of a system, in particular in the industrial environment, for forming a digital twin, characterized by means for carrying out one or more of the computer-assisted methods as described herein.

### BRIEF DESCRIPTION OF THE DRAWINGS

Further advantages and details of the teachings herein are explained on the basis of the exemplary embodiments which are illustrated in FIGS. 1 to 6. In the drawings:

FIG. 1 schematically shows a flowchart of an example method incorporating teachings of the present disclosure;

FIGS. 2A-2D schematically show principles of the image analysis incorporating teachings of the present disclosure of moving objects; and

FIGS. 3A-3F schematically show a selection of joint types on which the example method is based.

### DETAILED DESCRIPTION

Unless stated otherwise in the following description, the terms “carry out”, “implement”, “transform”, “transmit”, “calculate”, “computer-assisted”, “compute”, “determine”, “generate”, “configure”, “reconstruct”, “ascertain”, “capture” and the like preferably relate to actions and/or processes and/or processing steps which change and/or generate data and/or convert the data into other data, in which case the data are presented or may be present, in particular, as physical variables, for example as electrical pulses. In particular, the expression “computer” should be interpreted as broadly as possible in order to cover, in particular, all electronic devices with data processing properties. Computers can therefore be, for example, personal computers, servers, programmable logic controllers (PLC), handheld computer systems, pocket PC devices, mobile radio devices and other communication devices which can process data in a computer-assisted manner, processors and other electronic data processing devices.

In this disclosure, “computer-assisted” means an implementation of the method in which a processor carries out at least one method step of the method.

A processor includes a machine or an electronic circuit. A processor may be, in particular, a main processor (central processing unit, CPU), a microprocessor or a microcontroller. A processor may also be, for example, an IC (integrated circuit), in particular an FPGA (field programmable gate array) or an ASIC application-specific integrated circuit), or a DSP (digital signal processor) or a graphics processor GPU (graphic processing unit). A processor can be a virtualized processor, a virtual machine, or a soft CPU. It may also be, for example, a programmable processor which is equipped with configuration steps for carrying out said method according to the invention or is configured with configuration steps in such a manner that the programmable processor implements the features according to the invention of the method, of the component, of the modules, or of other aspects and/or partial aspects of the invention.

A “memory unit” or a “memory module” and the like may be understood as meaning, for example, a volatile memory in the form of random access memory (RAM) or a permanent memory such as a hard disk or a data carrier and a combination of one or more of these elements for forming a so-called cloud.

A “module” may include, for example, at least one processor and/or at least one memory unit for storing program instructions which are physically connected at a location, for example a part of a printed circuit board, in a functionally interacting manner. For example, the processor is specifically configured to execute the program instructions in such a manner that the processor performs functions in order to implement or realize the method according to the invention or a step of the methods. A processor, for example, may also carry out a plurality of the functions or steps of the method and can therefore implement one or more of the features mentioned according to claims.

A “parameter”, in particular of a digital twin, may include, a unit, for example a physical property, a name, a size, a color, a type, a state, a parameter of a place of use etc., or a feature, a characteristic and/or a configuration of the computer-assisted simulation model or product.

A “system” may include, in particular, a machine, for example a machine tool or a robot, a device, for example a field device, an industrial system, in particular formed from one or more of the elements mentioned above, for example a production system.

In an example method for forming a three-dimensional model of a system, in particular in the industrial environment, for forming a digital twin of the system, the following are carried out:
a) a first 3D scan of the system is created and stored at a first point in time by a first module,
b) at least one second 3D scan of the system is created and stored at at least one subsequent, second point in time by a second module on the basis of the capture result,
c) mobility properties of the system are captured by a third module,
d) the first 3D scan and/or the second 3D scans of the system is/are analyzed by a fourth module with respect to 3D geometries formed, in particular according to CAD methods, for each 3D scan,
e) the 3D scans of the system are analyzed by the fifth module on the basis of at least the recording time in order to ascertain movable and immovable 3D geometries of the respective scan of the system,
f) at least one property of the movement is ascertained for each movable 3D geometry by a sixth module,
g) the type of connection elements, for example joint type, between movable and immovable 3D geometries is determined by a seventh module, and
h) the 3D model is generated on the basis of the captured 3D geometries and the determined elements and is supplied to an eighth module as the basis for forming a digital twin.

The method described specifies a technical solution which makes it possible to create a 3D model for systems in an automated manner as far as possible. This is achieved by combining recourse to known 3D geometries and the derivation of properties of the movement, if movable geometries are included, which will generally be the case however, by considering the recordings over time, which makes it possible to determine connection elements and thus a 3D model that is completely kinematized as far as possible and can be taken as a basis for forming the digital twin.

An example arrangement for forming a three-dimensional model of a system, in particular in the industrial environment, for forming a digital twin is characterized by means for carrying out one or more of the methods and/or one of the developments of the method described herein. The arrangement makes it possible to implement the methods described herein and/or its developments and therefore, mutatis mutandis, to also achieve the advantages of the method and/or of its developments.

In some embodiments, depending on whether the mobility property is such that the system has at least one movable element, second 3D scans are captured and stored at so many second points in time that a 3D scan is captured and stored for each movable element substantially at all positions that can be assumed. In addition to the advantage that concealed parts of the system are also captured, with the result that the 3D geometries can be accurately formed, this also has the advantage that a plurality of perspectives are available for analyzing the movement. This may be advantageous, in particular, when ascertaining properties of the movement, in particular the degrees of freedom.

If the second points in time are continued in such a manner that a continuous sequence of 3D scans, in particular representing a flowing movement during visualization for an observer, is captured and stored, a streamable moving image sequence is generated. This supports, in particular, the creation of a derivation of movement properties, or the accurate creation of a movement profile becomes more precise.

In some embodiments, the second points in time are continued in such a manner that a sequence of 3D scans representing discrete locations, in particular at least end positions and/or turning points of a moving part of the system, in particular during visualization for an observer, is captured and stored. This improves the degree of precision even further when creating the movement profile since it is ensured that these significant points have a decisive influence on the determination of the profile.

In some embodiments, data describing a point cloud resulting in each case from the respective 3D scan are created and stored by an eighth module from at least a portion, in particular starting points, end points and/or turning points, of the stored 3D scans. Point clouds are particularly suitable as the result of a scan and can also be directly used to create and analyze 3D geometries. The generation and holding of the data therefore allow the steps of the methods described herein to be effectively carried out.

This advantage can be intensified or becomes very particularly important if, on the basis of the data describing point clouds, a tenth module:
a) compares 3D geometries determined by means of defined point cloud information, and stored in particular in a database, a cloud memory or the like, with points in the respective resulting point cloud, and
b) if a stored geometry matches, converts the matching part of the point cloud into the 3D geometry.

In some embodiments, a digital image sequence is generated for each moving stored geometry element in such a manner that, for each 3D scan,
a) a digital image is created on the basis of the 3D geometries,
b) wherein a fixed stored 3D geometry associated with the respective moving 3D geometry is created as a first representation within the digital image, and the moving 3D geometry is created as a second representation within the digital image,
c) and wherein the image sequence is created in such a manner that the second representation is placed in the respective point cloud resulting from the 3D scan in such a manner that the moving 3D geometry is gradually tracked within the boundary given by the resulting point cloud for each point cloud resulting from the 3D scan, and
d) the resulting image sequence is supplied to an image processing algorithm performed by an eleventh module in such a manner that the image processing algorithm carries out a pattern recognition using the image sequence in such a manner that a comparison with the movement patterns of known movable connection elements, in particular joints, is carried out and, if there is a match, the type of connection element is output as recognized and as an output signal in such a manner that a 3D geometry representing the connection element is defined, an envelope curve is generated, within which the second representation in the image sequence can be examined using image processing tools, such that the image analysis which is possible as a result can provide data relating to the movement and therefore a pattern identifying a connection element, in particular a joint, can be derived. This effectively automates the automatic recognition of connection elements.

In some embodiments, parameters of the connection element, in particular physical variables defining a movement profile, for example speed and/or acceleration, and/or geographical variables, such as end positions of the movement, are derived on the basis of the 3D scans. The 3D model or the digital twin can be parameterized accordingly using these data. In addition, these data are included in the pattern for recognizing the connection element and result in a more reliable determination of the connection element.

In some embodiments, the digital twin can be operated in a parameterized manner using the 3D model in such a manner that its state, on account of at least one parameter input, experiences a change which is output so as to be usable as the basis for an adjustment during operation and/or when setting up the system, the effects of the method on the physical environment are achieved by the resulting possible implementation of adjustments and/or improvements in the system.

In the example embodiments discussed below, the described components of the embodiments are each individual features which should be considered independently of one another and which also each develop the teachings independently of one another and can therefore also be considered to be part of the disclosure individually or in a combination other than that shown. Furthermore, the described embodiments can also be supplemented by more of the features that have already been described. Identical reference signs have the same meaning in the various figures.

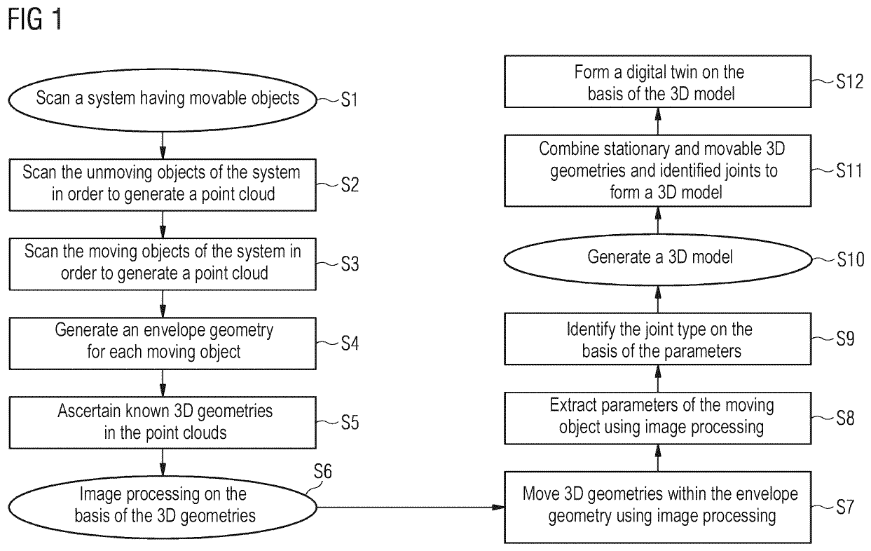

FIG. 1 schematically shows a flowchart of an example method for forming a three-dimensional model of a system, in particular in the industrial environment, for forming a digital twin of the system. It can be seen that the method begins in a first step S1 in a state “Scan a system having movable objects”.

The scanning can be carried out in this case using known arrangements such as stationary and/or mobile 3D scanners. Precision devices will generally provide the necessary accuracy, in particular in the industrial environment. However, the use of terminals enhanced with a 3D scanner function, for example cellphones, tablets and/or cameras with appropriate software which ensures accurate capture, is also conceivable.

Starting from this state, the system is scanned with the 3D scanner in a second step S2 in such a manner that the immovable objects are captured. This will generally be able to be implemented by means of one or a few scanning processes since the position of these objects does not change and therefore any scanning processes going beyond one scanning process are used, for example, only to capture concealed parts of the system.

On the basis of the second step S2, a point cloud representing the stationary objects of the system—at least at the recording time—is then ascertained for the subsequent steps and is held, for example, in a local memory device or, in particular, a memory device moved to the cloud.

In a third step S3, which can be carried out before or after the second step S2 in terms of time or even at least occasionally at the same time as the second step S2 is being carried out, the movable objects of the system are scanned.

For this purpose, scanning processes are carried out for all movable objects in such a manner that each moving object of the system is controlled such that it is moved into all positions which it can assume. This will generally be a movement which is carried out from a starting point and, depending on the degrees of freedom, via any turning/intermediate points, to at least one end point, in which case the control of all of these points is scanned. For example, the method may be configured in such a manner that simply all movements which are carried out by a system, for example of an assembly station, anyway according to implemented and executed control, such as the so-called “programmable logic controller” (programmable logic unit), during its function in the system are scanned.

Partially at the same time as and/or after the third step S3, a point cloud representing an envelope geometry and formed by the outer edges of the respective object is ascertained in a fourth step S4 for each object from the starting, intermediate and end points that have been approached. This envelope curve or the point cloud is likewise held for the further steps in accordance with the method.

In a fifth step S5, 3D geometries in the point clouds generated by the system are ascertained. In this case, this may act, for example, on the basis of 3D geometries which are known from so-called “computer aided design”, CAD, and from which 3D models can be generated using a CAD tool. These 3D geometries are made available for this purpose to the method, for example in a memory device configured as, in particular, a database with 3D geometries stored in a structured manner so as to be retrievable locally and/or via a network, with the result that the objects of the system can be composed by the available 3D geometries using the point clouds, formed to the greatest possible extent by the available 3D geometries.

In a further, the sixth, step S6, the method now changes to an image processing mode in which, in a seventh step S7, the envelope curves and the ascertained 3D geometries representing the moving objects of the system are now used such that individual images are generated for each moving object, in which images the 3D geometries representing the moving object are presented within the envelope curve in a manner gradually shifted from image to image from starting points, via any intermediate/turning points, to the end point(s), thus producing an image sequence representing the movement.

Information is now extracted from the individual images and/or the image sequence using common image processing tools, which information is used to form a 3D model which is intended to be used at least as a basis for a digital twin of the system. This information is extracted as parameters in an eighth step S8, in which case the parameters may be at least one or more of the following items of information:
The type of movement, that is to say, for example, a transverse movement, a rotational movement or a combination thereof can be derived as one of the parameters and can indicate a joint type.
The position of a joint can be derived as one of the parameters.
End positions of the movement can be ascertained as one of the parameters.
A movement profile can be derived; this may be determined, for example, by the speed or acceleration, which can be derived as a parameter.

On the basis of one or more of the parameters mentioned, the type of joint connecting the moving object to the unmoving object in the system can then be determined in a ninth step S9. If the joint type has been determined, the method according to the invention can change to the state “Generate 3D model”.

In this state, inter alia using the information automatically ascertained by the invention substantially using image processing, moving and unmoving 3D geometries will then be combined in an eleventh step S11 for each moving object in the point clouds using a model of the joint, such that a 3D model of the individual moving objects of the system and therefore a 3D model of the entire system can thus be generated in each case and can be supplied to the formation of a (3D) digital twin in a twelfth and last step S12, and virtual state changes can be caused by the digital twin and ultimately result in changes/adjustments in the real system.

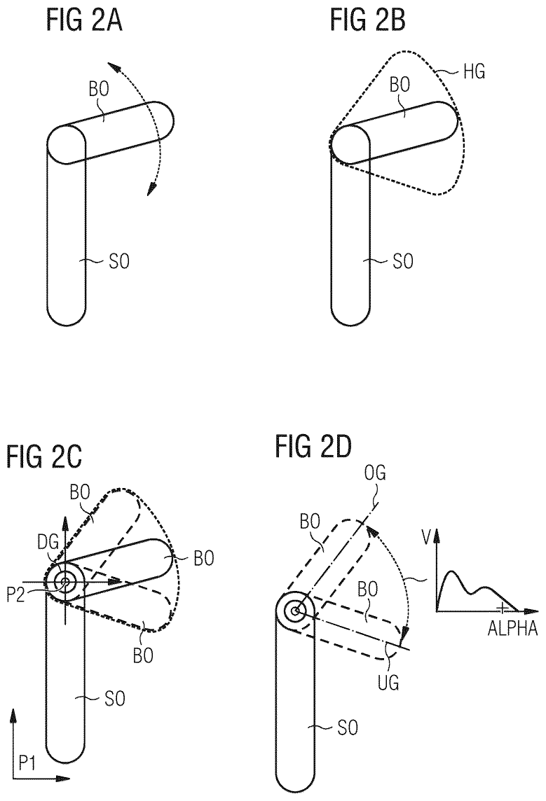

The method described is therefore used to avoid a manual, time-consuming process which would be needed to create the 3D digital twin without the teachings herein. Individual steps of the steps explained in the preceding figure are intended to be considered in somewhat more detail in FIG. 2 and in subfigures 2a to 2d.

FIG. 2a shows a part of the system consisting of a moving object BO and an immovable, stationary object SO which were scanned, for example, in the first step S1 and in the second step S2 and were stored as a point cloud—not illustrated. If the moving object BO is now allowed to assume all positions according to the third step S3, the envelope geometry HG resulting from the outer edges of the moving object BO is generated, as explained in the fourth step S4. The point cloud which represents the envelope geometry HG and is generated in this case is schematically indicated using dotted lines in FIG. 2b.

Parts of the parameters that can be ascertained using image processing are now shown by way of example in the subsequent subfigures 2c and 2d. Subfigure 2c schematically illustrates how the image processing ascertains parameters such as the position P1 of the stationary object SO, the type of joint, a rotary joint DG in the present example, and the position P2 of the joint DG. When moving the moving object to the positions which can be assumed, the image processing, that is to say the analysis of the image sequences, reveals that a rotational movement takes place around a fixed point. The position P2 of the rotary joint can be derived from the location of the fixed point, and the type of movement, rotation around the fixed point, and the outline of the envelope curve result in the joint being determined to be a rotary joint DG.

As a result of the positions being assumed by the movable object BO, it is also possible to ascertain, as schematically illustrated in the last subfigure 2d, the speed V and acceleration ALPHA of the movable object BO from the moving image sequence and the known variable of time that has elapsed during the movement from the lower limit UG to an upper limit.

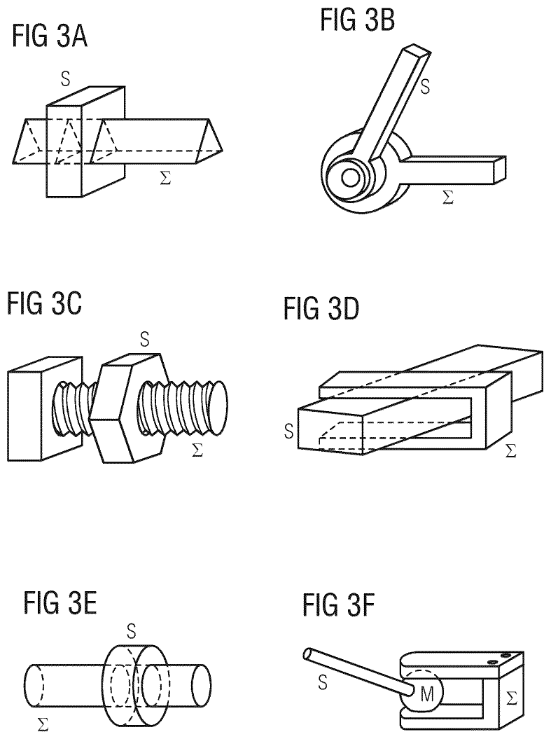

FIG. 3 and subfigures 3a to 3f show known types of joints. These known types are used in the recognition described. FIG. 3a is a sliding joint with the degree of freedom f=1,
FIG. 3 b is a rotary joint with the degree of freedom f=1,
FIG. 3c is a screw joint which can be pushed on a helix, that is to say has the degree of freedom f=1;
FIG. 3d is a plate joint in which a slider is mounted in a plane so as to be slidable and rotatable perpendicular thereto, that is to say has the degree of freedom f=3;
FIG. 3e is a rotary/sliding joint which is axially slidable and rotatable about an axis and therefore has a degree of freedom f=2,
FIG. 3f is a ball joint in which a ball is guided between two sockets opposite one another in the outer part, with the result that there is a degree of freedom of f=3.

This list is not exhaustive, but rather the most common joints are shown here only by way of example. There are further joints which are also included, for example the curved joint which is not illustrated and, like all further joint types not illustrated, is used as the basis for the recognition described herein. On the basis of the illustrated joints, the recognition of the joint type can be understood in somewhat more detail using an example of a joint that differs from the rotary joint DG recognized above.

For example, in the case of a sliding joint, such as that shown in

FIG. 3a, the image analysis described above according to image processing would show a shift between two end points within a rectangular envelope curve.

A degree of freedom of f=1 would therefore result. The rectangular envelope curve, the degree of freedom, the location of the moving object and of the stationary object with respect to one another when performing the movement would exclude the other joint types and would absolutely identify the sliding joint. If it were a ball joint, there would indeed be a fixed point, but the analysis of the movement, in contrast to the rotary joint, would reveal the movement around a plurality of axes, and the fixed point and the degrees of freedom would therefore define the ball joint as the joint type.

The advantage of recording the system and its moving parts from a plurality of perspectives and, in particular, supports the recognition of joints having a plurality of degrees of freedom, is also shown from this example. In other words, the exemplary embodiments that are shown are therefore used, as explained, to automatically generate a kinematized 3D (simulation) model consisting of CAD bodies and joints.

For generating a 3D model for the situations in which 3D models of the system components are not known, the teaching herein thus makes it possible to add these models using CAD and 3D scanners or even to generate them completely. So that the 3D model moves exactly like the real system, the components, for example CAD components, recognized after the scanning to be kinematized by automatically recognizing individual 3D geometries and incorporating them as it were.

The teachings herein therefore dispenses with manual processes such as the description of the movement, in order to generate a model. There is therefore no need to specify end positions and to program a travel profile between the end positions. This is also more advantageous than other alternatives which allow an automated procedure, for example obtaining the travel information via a connection to an external controller.

The teachings of the present disclosure are not restricted to the configurations and developments described. On the contrary, all developments that fall within the scope of protection of the claims and combinations of individual, multiple or all claimed features according to the claims are encompassed. Where use has been made above of expressions that suggest or imply a gender and/or other features suitable for differentiating between human beings, or may be perceived as such, these expressions have not been used discriminately, but rather inclusively, that is to say all human beings—regardless of given, self-adopted or assumed individual features—are considered to be equal.

What is claimed is:

1. A method for forming a three-dimensional, kinematic model of a system for forming a digital twin of the system, the method comprising:
creating and storing a first 3D scan of the system and at a first point in time using a first module;
creating and storing at least one second 3D scan of the system a subsequent, second point in time using a second module on the basis of the capture result;
capturing mobility properties of the system using a third module;
analyzing the first 3D scan and/or the second 3D scans of the system using a fourth module with respect to 3D geometries formed for each 3D scan;
analyzing the 3D scans of the system using a fifth module on the basis of a recording time in order to ascertain movable and immovable 3D geometries of the respective scan of the system;
ascertaining a property of the movement for each movable 3D geometry using a sixth module;
determining a type of each connection element between movable and immovable 3D geometries using a seventh module;
generating the three-dimensional model using the captured 3D geometries and the determined elements; and
supplying the model to an eighth module as the basis for forming a digital twin.

2. The method as claimed in claim 1, further comprising, depending on whether the mobility property is such that the system has at least one movable element, capturing and storing second 3D scans are at so many second points in time that a 3D scan is captured and stored for each movable element substantially at all positions that can be assumed.

3. The method as claimed in claim 2, wherein that the second points in time are continued so a continuous sequence of 3D scans is captured and stored.

4. The method as claimed in claim 2, wherein the second points in time are continued in such a manner that a sequence of 3D scans representing discrete locations is captured and stored.

5. The method as claimed in claim 1, further comprising creating and storing data describing a point cloud resulting in each case from the respective 3D scan using an eighth module from at least a portion of the stored 3D scans.

6. The method as claimed in claim 5, further comprising using tenth module on the basis of the data describing point clouds to:
compare 3D geometries determined by means of defined point cloud information, and stored in particular in a database with points in the respective resulting point cloud; and
if a stored geometry matches, converting the matching part of the point cloud into the 3D geometry.

7. The method as claimed in claim 6, further comprising generating a digital image sequence for each moving stored geometry element in such a manner that, for each 3D scan:
a) a digital image is created on the basis of the 3D geometries,
b) wherein a fixed stored 3D geometry associated with the respective moving 3D geometry is created as a first representation within the digital image, and the moving 3D geometry is created as a second representation within the digital image,
c) and wherein the image sequence is created in such a manner that the second representation is placed in the respective point cloud resulting from the 3D scan in such a manner that the moving 3D geometry is gradually tracked within the boundary given by the resulting point cloud for each point cloud resulting from the 3D scan, and
d) the resulting image sequence is supplied to an image processing algorithm performed by an eleventh module in such a manner that the image processing algorithm carries out a pattern recognition using the image sequence in such a manner that a comparison with the movement patterns of known movable connection elements, in particular joints, is carried out and, if there is a match, the type of connection element is output as recognized and as an output signal in such a manner that a 3D geometry representing the connection element is defined.

8. The method as claimed in claim 1, further comprising deriving parameters of the connection element are derived on the basis of the 3D scans.

9. The method as claimed in claim 1, wherein the digital twin can be operated in a parameterized manner using the 3D model in such a manner that its state, on account of at least one parameter input, experiences a change which is output so as to be usable as the basis for an adjustment during operation and/or when setting up the system.

10. (canceled)
